(19) United States
(12) Patent Application Publication
(10) Pub. No.: US 2008/0157132 A1
(43) Pub. Date: Jul. 3, 2008

(54) METHOD FOR FORMING THE GATE OF A TRANSISTOR

(76) Inventor: Dae-Young Kim, Chungcheongnam-do (KR)

Correspondence Address: SHERR & NOURSE, PLLC, 620 HERNDON PARKWAY, SUITE 200, HERNDON, VA, 20170, US

(21) Appl. No.: 11/953,571

(22) Filed: Dec. 10, 2007

(30) Foreign Application Priority Data
Dec. 27, 2006 (KR) 10-2006-0135687

(51) Int. Cl. H01L 21/336; H01L 29/78

(52) U.S. Cl. 257/288; 438/282; 257/E21.409; 257/E29.27

(57) ABSTRACT

A method of forming a gate of a transistor can include forming a nitride film over a semiconductor substrate; forming a photoresist pattern defining a gate channel region of a transistor over the nitride film; forming a nitride pattern by etching the nitride film using the photoresist pattern as a mask; removing the photoresist pattern; forming an oxide film over the semiconductor substrate using a thermal oxidation process; removing the nitride pattern to expose a portion of the surface of the semiconductor substrate corresponding to the removed nitride pattern; and then forming a recessed pattern corresponding to the gate channel region in the exposed semiconductor substrate.

The present application claims priority under 35 U.S.C. 119 to Korean Patent Application No. 10-2006-0135687 (filed on Dec. 27, 2006), which is hereby incorporated by reference in its entirety.

### BACKGROUND

High integration of a DRAM cell may be realized such that the size of a transistor may be miniaturized. Accordingly, the channel length between a source/drain may also be reduced. When the channel length decreases, however, a short channel effect of the transistor may be enhanced, thereby reducing a threshold voltage. Under the circumstances, in order to prevent the reduction of the threshold voltage resulting from the short channel effect of a transistor, a method of increasing a doping concentration of the channel may be utilized.

The increase of a doping concentration in the channel, however, may induce a field concentration effect at a source junction and may also increase the leakage current. Therefore, there is a problem that the refresh property of DRAM memory cell may be deteriorated.

### SUMMARY

Embodiments relate to a method for forming a recessed gate on and/or over a semiconductor substrate which can have a hollow shape.

Embodiments relate to a method for forming a gate of a transistor that can increase an effective channel length of the transistor without lowering the integration of a semiconductor device.

Embodiments relate to a method for forming a gate of a transistor that can decrease the reduction degree in a threshold voltage while maintaining the same integration.

Embodiments relate to a method for forming a gate of a transistor that can include at least one of the following steps: forming a nitride film over a semiconductor substrate; forming a photoresist pattern defining a gate channel region of a transistor over the nitride film; forming a nitride pattern by etching the nitride film using the photoresist pattern as a mask; removing the photoresist pattern; forming an oxide film over the semiconductor substrate using a thermal oxidation process; removing the nitride pattern to expose a portion of the surface of the semiconductor substrate corresponding to the removed nitride pattern; and then forming a recessed pattern corresponding to the gate channel region in the exposed semiconductor substrate.

Embodiments relate to a method for forming a gate of a transistor that can include at least one of the following steps: forming an oxide film over a semiconductor substrate; forming a photoresist pattern defining a gate channel region of a transistor over the oxide film; forming an oxide film pattern by etching the oxide film using the photoresist pattern as a mask; removing the photoresist pattern; forming a nitride film over the semiconductor substrate by performing a plasma nitridation treatment; removing the oxide pattern to expose a portion of the surface of the semiconductor substrate corresponding to the removed oxide pattern; and then forming a recessed pattern corresponding to the gate channel region in the exposed semiconductor substrate.

Embodiments relate to a semiconductor device that can include a semiconductor substrate having a recessed pattern formed therein; and a transistor formed over the recessed pattern. In accordance with embodiments, the transistor includes a gate oxide film formed over the recessed pattern and a gate poly formed over the gate oxide film.

### DRAWINGS

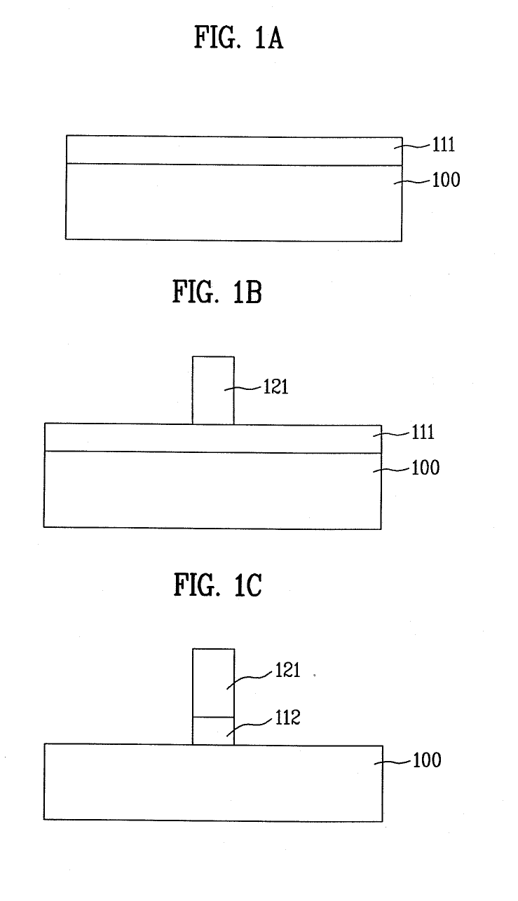

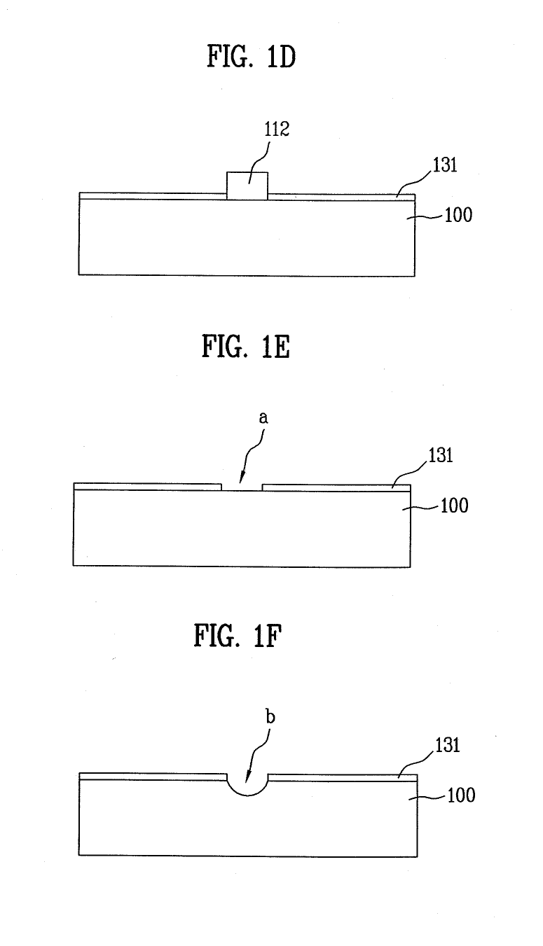

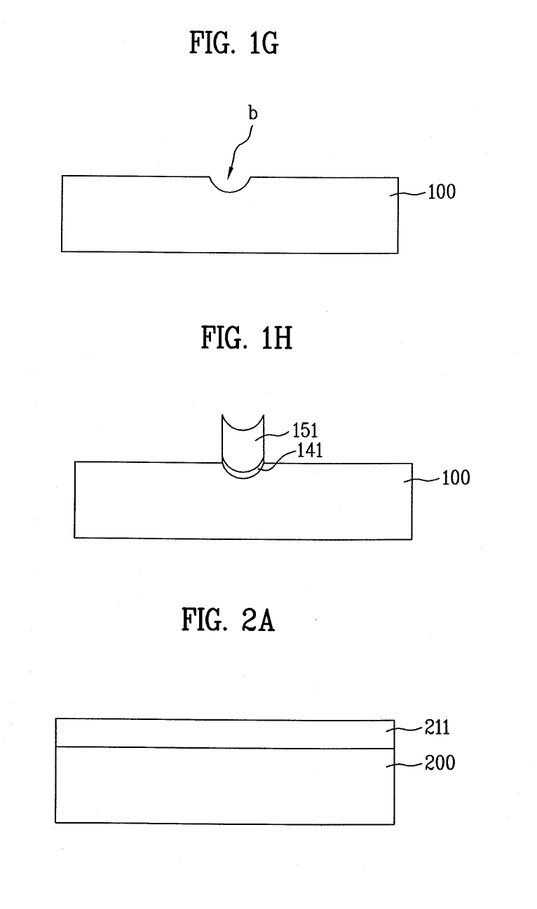

Example FIGS. 1A to 1H illustrate a method for forming a gate of a transistor, in accordance with embodiments.

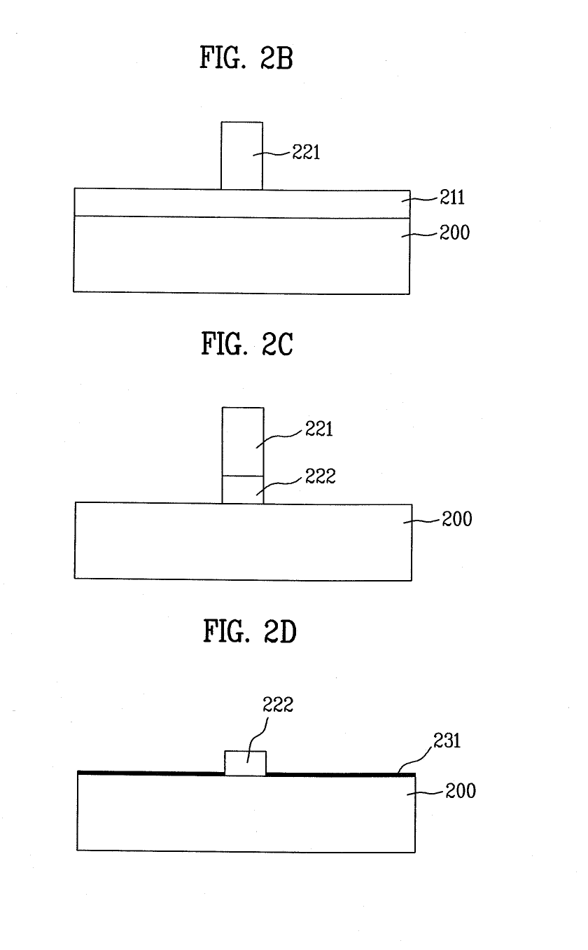

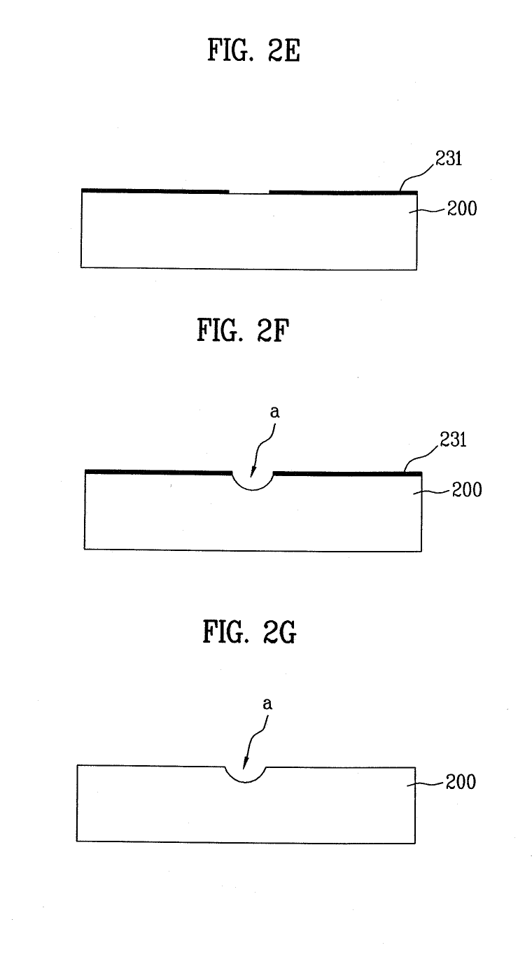

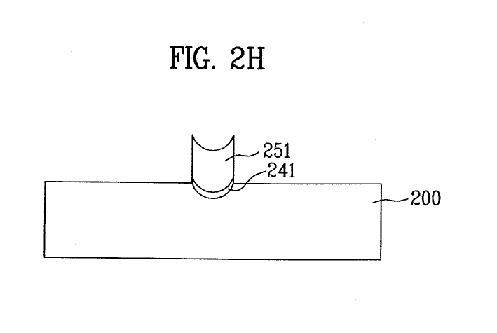

Example FIGS. 2A to 2H illustrate a method for forming a gate of a transistor, in accordance with embodiments.

### DESCRIPTION

As illustrated in example FIG. 1A, in accordance with embodiments a method for forming a gate of a transistor can include forming nitride film 111 such as silicon nitride (SiN) on and/or over the surface of semiconductor substrate 100. A silicon substrate can be used as semiconductor substrate 100. Nitride film 111 can be formed by a low pressure (LP) chemical vapor deposition (CVD) process with a predetermined thickness such as between 100 to 200 Å.

As illustrated in example FIG. 1B, a photoresist can then be coated on and/or over the surface of nitride film 111. A fine pattern or photoresist pattern 121 can then be formed defining a gate channel region of a transistor through a lithographic process. Fine pattern 121 can be a region where the gate of a transistor can be formed. Thus, depending on the size of the transistor to be fabricated, the height and width of fine pattern 121 can be adjustable.

As illustrated in example FIG. 1C, the exposed portion of nitride film 111 can then be removed by a dry etching process using fine pattern 121 as a mask to form nitride pattern 112.

As illustrated in example FIG. 1D, fine pattern 121 composed of the photoresist can then be removed, and then a thermal oxidation process can be performed. Oxide film 131 can then be formed on and/or over the exposed surface of semiconductor substrate 100, i.e., on both sides of nitride pattern 112. Oxide film 131 can be formed by a thermal oxidation process and can have a thickness of 20 Å or less.

As illustrated in example FIG. 1E, nitride film pattern 112 can then be removed to expose the uppermost surface of semiconductor substrate 100. Nitride film pattern 112 can be removed by a wet etching process that can include phosphoric acid. As a result, the space where the nitride film pattern 112 is removed becomes an opening ‘a’ due to oxide films 131 existing on both sides of the opening ‘a.’ A chemical mechanical planarization (CMP) process can then be performed on the overall surface of semiconductor substrate 100 in order to grind the silicon semiconductor substrate 100 exposed by opening ‘a.’

As illustrated in example FIG. 1F, as a result of the CMP process the exposed uppermost surface of silicon semiconductor substrate 100 can be removed to form a substantially semi-circular configuration or pattern ‘b’ by a dishing effect.

As illustrated in example FIG. 1G, thermal oxide film 131 can then be removed by a buffered oxide etching (BOE) process using an oxide etchant. Therefore, substantially semi-circular recessed pattern ‘b’ can be formed in the surface of semiconductor substrate 100.

As illustrated in example FIG. 1H, a transistor can be formed in recessed pattern ‘b’ of semiconductor substrate 100 by forming gate oxide film 141 on and/or over semi-circular recessed pattern ‘b’ of semiconductor substrate 100 and then forming gate poly 151 on and/or over gate oxide film 141 by performing a transistor fabrication process. Additional processes of the art for completing the transistor can be conducted in accordance with embodiments.

Accordingly, in accordance with embodiments, a round pattern-type recessed gate channel can be realized using thermal oxide film 131 as a hard mask.

As illustrated in example FIG. 2A, in accordance with embodiments, a method for forming a gate of a transistor can include forming thermal oxide film 211 on and/or over the surface of silicon semiconductor substrate 200. Thermal oxide film 211 can have a predetermined thickness of between 100 to 200 Å.

As illustrated in example FIG. 2B, a photoresist can then be coated on and/or over the surface of oxide film 211. Fine pattern (or photoresist pattern) 221 can then be formed defining a gate channel region of a transistor through a lithographic process. Fine pattern 221 can be a region where a gate of a transistor can be formed. Thus, depending on the size of the transistor to be fabricated, the height and width of fine pattern 221 can be adjustable.

As illustrated in example FIG. 2C, exposed portions of oxide film 211 can then be removed by a dry etching process using fine pattern 221 as a mask to form oxide pattern 222.

As illustrated in example FIG. 2D, after removing photoresist 221, a plasma nitridation treatment can be performed on and/or over the surface of semiconductor substrate 200 to form a thin layer of nitride film 231 such as silicon nitride (SiN) on and/or over the surface of semiconductor substrate 200.

As illustrated in example FIG. 2E, oxide film pattern 222 can then be removed by an etching process to expose a portion of the uppermost surface of semiconductor substrate 200. A CMP process can then be performed on the overall surface of semiconductor substrate 200 to grind the exposed silicon semiconductor substrate 200. The CMP process can be performed with the consideration of the grinding difference between the pure silicon and the nitride film. To obtain a desired dishing effect, it may be set the grinding rate against the silicon to increase.

As illustrated in example FIG. 2F, as a result of the CMP process, the surface of exposed semiconductor substrate 200 can be formed as a substantially semi-circular recessed pattern ‘a’ by a dishing effect.

As illustrated in example FIG. 2G, nitride film 231 can be removed is removed using a wet etching process that can include phosphoric acid.

As illustrated in example FIG. 2H, a transistor can be formed in recessed pattern ‘a’ of semiconductor substrate 100 by forming gate oxide film 241 on and/or over semi-circular recessed pattern ‘a’ of semiconductor substrate 200 and then forming gate poly 251 on and/or over gate oxide film 241 by performing a transistor fabrication process. Additional processes of the art for completing the transistor can be conducted in accordance with embodiments. In accordance with embodiments, the recessed gate of a transistor can be formed on and/or over the surface of semiconductor substrate 200 by using a plasma nitridation treatment.

Accordingly, in accordance with embodiments, by forming an effective channel length of the gate of a transistor in a substantially semi-circular or spherical configuration to elongate the effective channel length. Meaning, by forming a gate channel in a recessed configuration, the method in accordance with embodiments can prevent a decrease in the threshold voltage of the transistor due to an increase in the integration of a semiconductor device. Additionally, by having the effective channel length elongated, the decrease degree in the threshold voltage can be reduced while maintaining the same integration.

Although embodiments have been described herein, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method comprising:
forming a nitride film over a semiconductor substrate;
forming a photoresist pattern defining a gate channel region of a transistor over the nitride film;
forming a nitride pattern by etching the nitride film using the photoresist pattern as a mask;
removing the photoresist pattern;
forming an oxide film over the semiconductor substrate using a thermal oxidation process;
removing the nitride pattern to expose a portion of the surface of the semiconductor substrate corresponding to the removed nitride pattern; and then
forming a recessed pattern corresponding to the gate channel region in the exposed semiconductor substrate.

2. The method of claim 1, further comprising removing the oxide film after forming the recessed pattern.

3. The method of claim 2, further comprising sequentially forming a gate oxide film and a gate poly of a transistor over the recessed pattern.

4. The method of claim 1, wherein the height and width of the photoresist pattern is determined depending on the size of the transistor.

5. The method of claim 1, wherein the nitride film pattern is removed by a wet etching process.

6. The method of claim 1, wherein the recessed pattern is formed using a chemical mechanical planarization process.

7. The method of claim 1, wherein the nitride film is formed using a low pressure chemical vapor deposition process.

8. The method of claim 1, wherein the nitride film has a predetermined thickness.

9. The method of claim 1, wherein the predetermined thickness is between 100 to 200 Å.

10. The method of claim 1, wherein the oxide film is formed using a thermal oxidation process.

11. The method of claim 1, wherein the oxide film has a predetermined thickness.

12. The method of claim 1, wherein the predetermined thickness is 20 Å or less.

13. The method of claim 1, wherein the nitride film comprises silicon nitride.

14. A method comprising:
forming an oxide film over a semiconductor substrate;
forming a photoresist pattern defining a gate channel region of a transistor over the oxide film;
forming an oxide film pattern by etching the oxide film using the photoresist pattern as a mask;
removing the photoresist pattern;
forming a nitride film over the semiconductor substrate by performing a plasma nitridation treatment;
removing the oxide pattern to expose a portion of the surface of the semiconductor substrate corresponding to the removed oxide pattern; and then
forming a recessed pattern corresponding to the gate channel region in the exposed semiconductor substrate.

15. The method of claim 14, further comprising removing the nitride film after forming the recessed pattern.

16. The method of claim 14, further comprising sequentially forming a gate oxide film and a gate poly of the transistor over the recessed pattern.

17. The method of claim 14, wherein the oxide film is formed using a thermal oxidation process.

18. The method of claim 14, wherein the recessed pattern is formed using a chemical mechanical planarization process.

19. An apparatus comprising:
a semiconductor substrate having a recessed pattern formed therein; and
a transistor formed over the recessed pattern,
wherein the transistor includes a gate oxide film formed over the recessed pattern and a gate poly formed over the gate oxide film.

20. The apparatus of claim 19, wherein the recessed pattern has a substantially semi-circular configuration.
